(19) United States
(12) Patent Application Publication
(10) Pub. No.: US 2022/0293397 A1
(43) Pub. Date: Sep. 15, 2022

(54) SUBSTRATE EDGE RING THAT EXTENDS PROCESS ENVIRONMENT BEYOND SUBSTRATE DIAMETER

(71) Applicant: Applied Materials, Inc., Santa Clara, CA (US)

(72) Inventors: Michael R. RICE, Pleasanton, CA (US); Kenneth S. COLLINS, San Jose, CA (US); James David CARDUCCI, Sunnyvale, CA (US); Shahid RAUF, Pleasanton, CA (US); Kartik RAMASWAMY, San Jose, CA (US)

(21) Appl. No.: 17/198,141

(22) Filed: Mar. 10, 2021

(51) Int. Cl. H01J 37/32; H01L 21/67; H01L 21/683

(52) U.S. Cl. CPC H01J 37/32642; H01L 21/67069; H01L 21/6833; H01J 37/32724; H01J 2237/2007; H01J 2237/002; H01J 2237/334

(57) ABSTRACT

Embodiments of substrates supports for use in process chambers are provided herein. In some embodiments, a substrate support includes: a dielectric plate having a first side configured to support a substrate having a given diameter and including an annular groove disposed in the first side, wherein the annular groove has an inner diameter that is less than the given diameter and an outer diameter that is greater than the given diameter, wherein the dielectric plate includes a chucking electrode; an insert ring disposed in the annular groove of the dielectric plate; and an edge ring disposed on the dielectric plate, wherein the edge ring has an inner diameter that is greater than the given diameter and less than the outer diameter of the annular groove such that the edge ring is disposed over a portion of the insert ring.

### FIELD

Embodiments of the present disclosure generally relate to substrate processing systems, and more specifically, to substrate supports for use in substrate processing systems.

### BACKGROUND

Substrate processing systems typically include process chambers for performing a desired process, such as an etch process, on one or more substrates disposed therein. Radio frequency (RF) power is often used in etching processes, for example, requiring very high aspect ratio holes to make contacts or deep trenches for laying infrastructure for electrical pathways. RF power can be used for plasma generation and/or for creating bias voltage on a substrate being processed to attract ions from bulk plasma. An electrostatic chuck is used to electrostatically hold a substrate to control substrate temperature during processing. The electrostatic chuck typically includes an electrode embedded in a dielectric plate. The process chamber may include an edge ring that is disposed about the substrate to guide a substrate or to protect the periphery of the electrostatic chuck from plasma exposure.

The inventors have observed that as a height of the edge ring comes down due to ion bombardment during substrate processing, equipotential lines in a sheath created by the bias RF power source become tilted proximate the edge ring, causing process drift. A temperature differential between the edge ring and the dielectric plate may cause a non-uniform chemical reaction between the edge ring and process gases as compared to the dielectric plate and process gases, causing process drift. To reduce the tilt in the equipotential lines of the sheath (and thus in the trajectories of ions impinging upon the substrate), RF power may be independently coupled to the edge ring to control the sheath. More RF power to the edge ring expands the sheath and less RF power shrinks the sheath. As the edge ring is etched, the edge ring becomes thinner, requiring more RF power over a lifetime of the edge ring to reduce the tilt of the sheath. However, the increased RF power to the edge ring also increases etch rate of the edge ring and increases the edge ring temperature and ion flux which can cause process drift. Further, conventional edge rings operating at elevated temperatures may stick to an underlying component, requiring humans to remove and replace edge rings, which increases processing down time and reduces substrate throughput.

Accordingly, the inventors have provided embodiments of improved substrate supports.

### SUMMARY

Embodiments of substrates supports for use in process chambers are provided herein. In some embodiments, a substrate support for use in a substrate processing chamber includes: a dielectric plate having a first side configured to support a substrate having a given diameter and including an annular groove disposed in the first side, wherein the annular groove has an inner diameter that is less than the given diameter and an outer diameter that is greater than the given diameter, wherein the dielectric plate includes a chucking electrode; an insert ring disposed in the annular groove of the dielectric plate; and an edge ring disposed on the dielectric plate, wherein the edge ring has an inner diameter that is greater than the given diameter and less than the outer diameter of the annular groove such that the edge ring is disposed over a portion of the insert ring.

In some embodiments, a substrate support for use in a substrate processing chamber includes: a dielectric plate having a first side configured to support a substrate having a given diameter and including an annular groove disposed in the first side, wherein the annular groove has an inner diameter that is less than the given diameter and an outer diameter that is greater than the given diameter, wherein the dielectric plate includes one or more chucking electrodes; an insert ring disposed in the annular groove of the dielectric plate, wherein the insert ring has a thickness less than a thickness of the dielectric plate; and an edge ring disposed on the dielectric plate, wherein the edge ring has an inner diameter that is greater than the given diameter and less than the outer diameter of the annular groove such that the edge ring is disposed over a portion of the insert ring.

In some embodiments, a process chamber for processing a substrate includes: a chamber body having a substrate support disposed within an inner volume of the chamber body, wherein the substrate support includes: a cooling plate; a dielectric plate having a first side configured to support a substrate having a given diameter and including an annular groove disposed in the first side, wherein the annular groove has an inner diameter that is less than the given diameter and an outer diameter that is greater than the given diameter, wherein the dielectric plate includes a chucking electrode; an insert ring disposed in the annular groove of the dielectric plate; and an edge ring disposed on the dielectric plate, wherein the edge ring has an inner diameter that is greater than the given diameter and less than the outer diameter of the annular groove such that the edge ring is disposed over a portion of the insert ring, and wherein the dielectric plate includes one or more backside gas channels disposed below the edge ring.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a process chamber having a substrate support in accordance with at least some embodiments of the present disclosure.

FIG. 2 depicts a cross-sectional schematic partial side view of a substrate support in accordance with at least some embodiments of the present disclosure.

FIG. 3 depicts a schematic partial side view of a substrate support in accordance with at least some embodiments of the present disclosure.

FIG. 4 depicts a cross-sectional schematic partial side view of a substrate support in accordance with at least some embodiments of the present disclosure.

FIG. 5 depicts a schematic side view of a portion of a process chamber having a substrate support in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of substrate supports and edge rings for use in a substrate processing chamber are provided herein. The substrate support includes a dielectric plate having a support surface to support a substrate having a given diameter. The substrate support includes an edge ring disposed on the dielectric plate and configured to surround the substrate. A single power source may be coupled to the substrate support to provide power at a similar power density to locations corresponding to the substrate and the edge ring. The single power source may be configured to provide power at one or more frequencies or waveforms. As such, the edge ring disposed about the substrate advantageously extends a process environment beyond the given diameter of the substrate diameter, minimizing process drift at an edge of the substrate. The edge ring and the dielectric plate may advantageously be thermally isolated from each other or have independent backside gas channels to provide independent temperature control of the edge ring and the dielectric plate. An insert ring is advantageously provided in an annular groove in the dielectric plate at a location beneath a gap between the substrate and the edge ring to protect the dielectric plate.

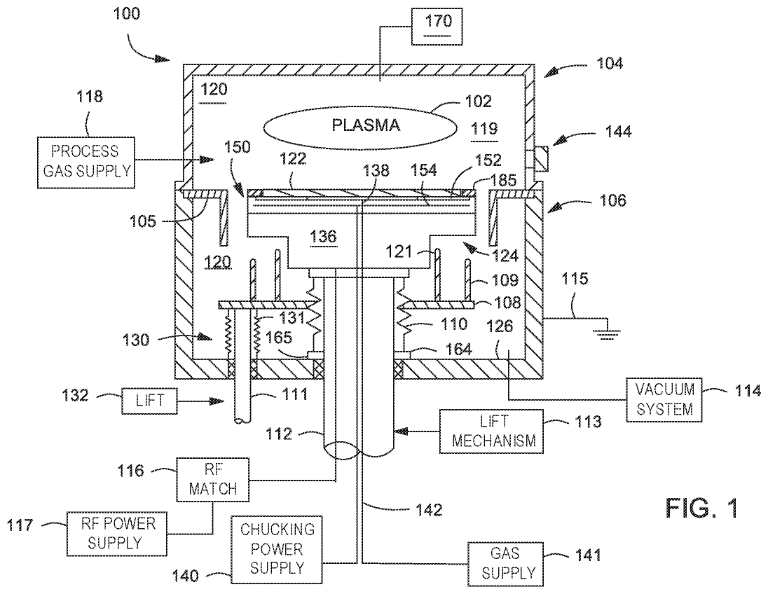

FIG. 1 depicts a schematic side view of a process chamber (e.g., a plasma processing chamber) having a substrate support in accordance with at least some embodiments of the present disclosure. In some embodiments, the plasma processing chamber is an etch processing chamber. However, other types of processing chambers configured for different processes can also use or be modified for use with embodiments of the substrate supports described herein.

The process chamber, or chamber 100, is a vacuum chamber which is suitably adapted to maintain sub-atmospheric pressures within a chamber interior volume 120 during substrate processing. The chamber 100 includes a chamber body 106 covered by a lid 104 which encloses a processing volume 119 located in the upper half of chamber interior volume 120. The chamber 100 may also include one or more shields 105 circumscribing various chamber components to prevent unwanted reaction between such components and ionized process material. The chamber body 106 and lid 104 may be made of metal, such as aluminum. The chamber body 106 may be grounded via a coupling to ground 115.

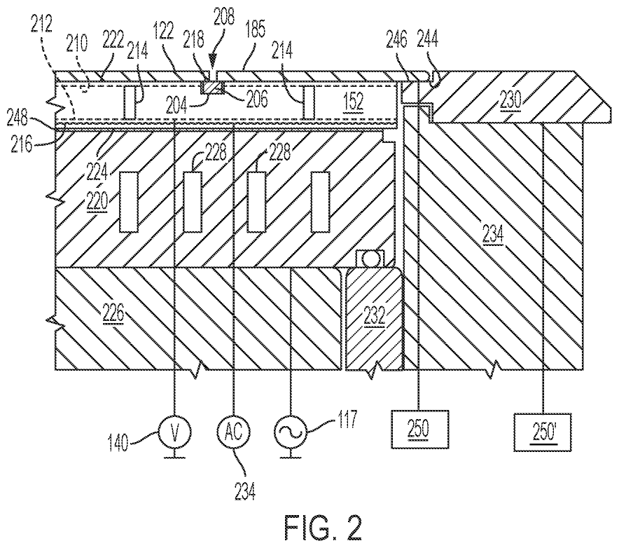

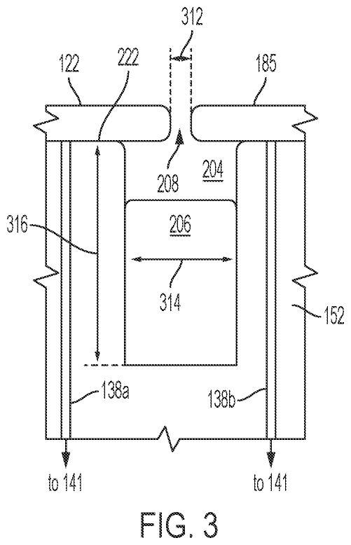

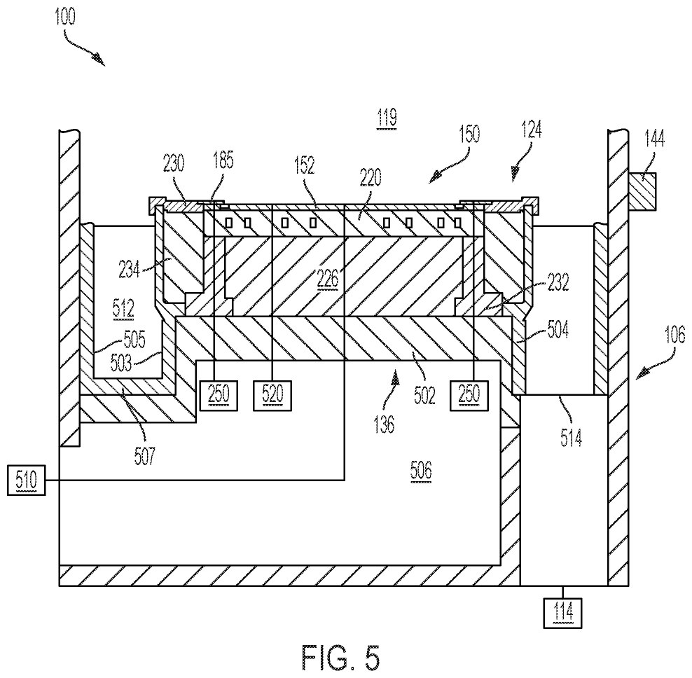

A substrate support 124 is disposed within the chamber interior volume 120 to support and retain a substrate 122, such as a semiconductor wafer, for example, or other such substrate as may be electrostatically retained. The substrate support 124 may generally comprise a pedestal 150 (described in more detail below with respect to FIGS. 2-5). The pedestal 150 comprises a dielectric plate 152 disposed on a base assembly 136. In some embodiments, as shown in FIG. 1, the substrate support 124 comprises and a support shaft 112 for supporting the pedestal 150. In some embodiments, as shown and discussed below with respect to FIG. 5, the pedestal 150 may be directly coupled to the chamber body 106 via the base assembly 136. The substrate support 124 includes an edge ring 185 (described in more detail below with respect to FIGS. 2-3) disposed on the dielectric plate 152.

The dielectric plate 152 includes one or more chucking electrodes 154 configured to electrostatically chuck the substrate 122 to the dielectric plate 152. The one or more chucking electrodes 154 may also electrostatically chuck the edge ring 185 to the dielectric plate 152.

The support shaft 112 provides a conduit to provide, for example, backside gases, process gases, fluids, coolants, power, or the like, to the pedestal 150. In some embodiments, the support shaft 112 is coupled to a lift mechanism 113, such as an actuator or motor, which provides vertical movement of the pedestal 150 between an upper, processing position (as shown in FIG. 1) and a lower, transfer position (not shown). A bellows assembly 110 is disposed about the support shaft 112 and is coupled between the pedestal 150 and a bottom surface 126 of chamber 100 to provide a flexible seal that allows vertical motion of the pedestal 150 while preventing loss of vacuum from within the chamber 100. The bellows assembly 110 also includes a lower bellows flange 164 in contact with an o-ring 165 or other suitable sealing element which contacts the bottom surface 126 to help prevent loss of chamber vacuum.

In some embodiments, the support shaft 112 facilitates coupling a backside gas supply 141, a chucking power supply 140, and RF sources (e.g., RF plasma power supply 170 and a bias power supply 117) to the pedestal 150. In some embodiments, the bias power supply 117 includes one or more RF bias power sources. In some embodiments, RF energy supplied by the RF plasma power supply 170 may have a frequency of about 400 kHz to over 40 MHz. The backside gas supply 141 is disposed outside of the chamber body 106 and supplies heat transfer gas to the pedestal 150. In some embodiments, a RF plasma power supply 170 and a bias power supply 117 are coupled to the pedestal 150 via respective RF match networks (only RF match network 116 shown). In some embodiments, the substrate support 124 may alternatively include AC, DC, or RF bias power. In some embodiments, the AC, DC, or RF bias power may be pulsed. In some embodiments, as shown and described in FIG. 5, the support shaft 112 is not coupled to a lift mechanism 113 and is fixedly coupled to the chamber body 106.

The chamber 100 may include a second lift 130. The second lift 130 can include lift pins 109 mounted on a platform 108 connected to a shaft 111 which is coupled to a second lift mechanism 132 for raising and lowering the second lift 130 so that the edge ring 185 may be placed on or removed from the pedestal 150. In some embodiments, each of the lift pins 109 are not mounted to a common platform and are independently controllable. In some embodiments, the second lift 130 may be coupled to lift pins 121 configured to raise or lower the substrate 122 onto or off of the pedestal 150. The second lift 130 may comprise a plurality of lift mechanisms for independently controlling the lift pins 109 or the lift pins 121. The pedestal 150 may include through holes to receive one or more of the lift pins 109 or the lift pins 121.

A bellows assembly 131 is coupled between the second lift 130 and bottom surface 126 to provide a flexible seal which maintains the chamber vacuum during vertical motion of the second lift 130. In some embodiments, as shown in FIG. 1, the second lift 130 is disposed outside of the support shaft 112. In some embodiments, the second lift 130 is disposed inside or radially inward of the support shaft 112.

In some embodiments, the pedestal 150 includes gas distribution channels 138 extending from a lower surface of the pedestal 150 (e.g., bottom surface of the base assembly 136) to various openings in an upper surface of the pedestal 150. The gas distribution channels 138 are configured to provide backside gas, such as nitrogen (N) or helium (He), to the top surface of the pedestal 150 to act as a heat transfer medium. The gas distribution channels 138 are in fluid communication with the backside gas supply 141 via gas conduit 142 to control the temperature and/or temperature profile of the pedestal 150 during use. In some embodiments, the gas distribution channels 138 are configured to provide gas pressure for heat transfer and temperature control of the edge ring 185 independently from a temperature of the dielectric plate 152.

The chamber 100 is coupled to and in fluid communication with a vacuum system 114 which includes a throttle valve (not shown) and vacuum pump (not shown) which are used to exhaust the chamber 100. The pressure inside the chamber 100 may be regulated by adjusting the throttle valve and/or vacuum pump. The chamber 100 is also coupled to and in fluid communication with a process gas supply 118 which may supply one or more process gases to the chamber 100 for processing a substrate disposed therein.

The chamber 100 includes a slit valve 144 to facilitate transferring the substrate 122 into and out of the chamber interior volume 120. In some embodiments, a transfer robot (not shown) is configured to transfer the substrate 122. The transfer robot may also advantageously be configured to transfer the edge ring 185 into and out of the chamber interior volume 120 for replacement. In some embodiments, the transfer robot may be configured to place the edge ring 185 and the substrate 122 into the chamber interior volume 120 within a repeatability of plus or minus about 50 micrometers. The slit valve 144 may be coupled to the lid 104 or chamber body 106.

In operation, for example, a plasma 102 may be created in the chamber interior volume 120 to perform one or more processes. The plasma 102 may be created by coupling power from a plasma power source (e.g., RF plasma power supply 170) to a process gas via one or more chucking electrodes near or within the chamber interior volume 120 to ignite the process gas and creating the plasma 102. A bias power may be provided from a bias power supply (e.g., bias power supply 117) to the pedestal 150 to attract ions from the plasma 102 towards the substrate 122. The bias power supply 117 may supply bias power to the edge ring 185 and the dielectric plate 152. For example, the bias power supply 117 may comprise a single power supply that is shared by both the edge ring 185 and the dielectric plate 152.

FIG. 2 depicts a cross-sectional schematic partial side view of a substrate support, suitable for use as substrate support 124, in accordance with at least some embodiments of the present disclosure. The substrate support 124 includes the dielectric plate 152 having a first side 222 configured to support the substrate 122 having a given diameter and a second side 224 opposite the first side 222. The dielectric plate 152 includes an annular groove 204 disposed in the first side 222. The annular groove 204 has an inner diameter that is less than the given diameter and an outer diameter that is greater than the given diameter. In some embodiments, the given diameter is about 11 inches to about 13 inches, for example, the substrate 122 can be a 300 mm diameter semiconductor wafer, or the like. In some embodiments, the dielectric plate 152 is made of aluminum nitride (AlN), aluminum oxide (Al₂O₃), or the like. In some embodiments, a thickness of the dielectric plate 152 is about 3 to about 12 mm. In some embodiments, the thickness of the dielectric plate 152 is about 5 to about 10 mm.

In some embodiments, a heating element 216 is disposed in the dielectric plate 152 to heat the dielectric plate 152 to a suitable temperature. In some embodiments, the heating element 216 extends radially outward beyond the annular groove 204 and beneath the edge ring 185 disposed on the dielectric plate 152. The heating element 216 may be coupled to a power source 252 to power the heating element 216. In some embodiments, the power source 252 is an AC power source. In some embodiments, a temperature probe may be embedded within or otherwise coupled to the edge ring 185 to monitor and control a temperature of the edge ring 185 by controlling the power applied to the heating element 216 by the power source 252.

The dielectric plate 152 includes one or more chucking electrodes 154 embedded therein. The one or more chucking electrodes 154 may be monopolar or bipolar. In some embodiments, the one or more chucking electrodes 154 comprise an upper electrode 210, a lower electrode 212, and a plurality of posts 214 electrically coupling the upper electrode 210 and the lower electrode 212. The upper electrode 210 and the lower electrode 212 may comprise a mesh, a foil, a plate, or the like. In some embodiments, at least one of the upper electrode 210, the lower electrode 212, and the plurality of posts 214 are made of molybdenum. In some embodiments, the one or more chucking electrodes 154 extend radially outward of the annular groove 204 and beneath the edge ring 185 to electrically chuck the edge ring 185 to the dielectric plate 152. In some embodiments, the upper electrode 210 is disposed less than 1.0 mm from the first side 222 to advantageously reduce arcing. In some embodiments, the lower electrode 212 is disposed less than 1.0 mm from the second side 224 to advantageously reduce arcing.

An insert ring 206 is disposed in the annular groove 204 of the dielectric plate 152. In some embodiments, the insert ring 206 is made of silicon (Si), silicon nitride (SiN), silicon carbide (SiC), silicon oxide (SiO₂), or quartz. In some embodiments, the insert ring 206 has a width sized to substantially fit in the annular groove 204. In some embodiments, as shown in FIG. 2, the insert ring 206 is separate from the edge ring 185. In some embodiments, the edge ring 185 is made of a different material than the insert ring 206. A thickness of the insert ring 206 is generally less than the thickness of the dielectric plate 152. In some embodiments, the thickness of the insert ring 206 is about 3 to about 11 millimeters. In some embodiments, an upper surface 218 of the insert ring 206 is coplanar with an upper surface, or first side 222, of the dielectric plate 152.

The edge ring 185 may generally comprise a flat circular disk with a central opening. A thickness of the edge ring 185 may be similar to a thickness of the substrate 122. In some embodiments, a thickness of the edge ring 185 is about 650 micrometers to about 1300 micrometers. The edge ring 185 is disposed on the dielectric plate 152, for example, at an outer portion of the dielectric plate 152 and configured to surround the substrate 122. In some embodiments, the edge ring 185 is made of ceramic material. In some embodiments, the edge ring 185 is made of silicon (Si), silicon carbide (SiC), silicon dioxide (SiO₂), or silicon nitride (SiN). The edge ring 185 has an inner diameter that is greater than the given diameter and less than the outer diameter of the annular groove 204 such that the edge ring 185 is disposed over a portion of the insert ring 206. In some embodiments, an inner diameter of the edge ring is about 297 mm to about 302 mm. In some embodiments, an outer diameter of the edge ring is about 350 mm to about 450 mm. In some embodiments, the outer diameter of the edge ring 185 is greater than an outer diameter of the dielectric plate.

The inner diameter of the edge ring 185 being greater than the given diameter forms a gap 208 therebetween. In some embodiments, a width 312 of the gap 208 is advantageously small such that the inner diameter of the edge ring 185 is about 0.5 mm to about 1.0 mm greater than the given diameter. The insert ring 206 disposed below the gap 208 advantageously protects the dielectric plate 152 from plasma during processing. The gap 208 having a small width advantageously reduces or minimizes tilting of the equipotential lines of the sheath (or the trajectories of impinging ions) above an interface between the substrate 122 and the edge ring 185. The reduced or minimized tilting effectively extends a process environment beyond the given diameter of the substrate 122, resulting in increased etch uniformity across the substrate 122. The gap 208 having a small width also reduces ion bombardment of the insert ring 206 from the plasma 102, extending the life of the insert ring 206.

FIG. 3 depicts a schematic partial side view of a substrate support 124 in accordance with at least some embodiments of the present disclosure. In some embodiments, a width 314 of the annular groove 204 is about 2 mm to about 4 mm. In some embodiments, the substrate 122 overlaps about 0.5 mm to about 1.5 mm over the annular groove 204. In some embodiments, the edge ring 185 overlaps about 0.5 mm to about 1.5 mm over the annular groove 204. In some embodiments, a depth 316 of the annular groove 204 is about 4 mm to about 10 mm. In use, ions from the plasma 102 bombard the insert ring 206 and the edge ring 185. FIG. 3 depicts the insert ring 206 after some ion bombardment, where an upper surface of the insert ring 206 is no longer coplanar with the upper surface of the dielectric plate 152. The insert ring 206 and the edge ring 185 are periodically replaced, as needed.

In some embodiments, the gas distribution channels 138 include first gas distribution channels 138a extending from the second side 224 to the first side 222 of the dielectric plate 152 beneath a support surface of the substrate 122. In some embodiments, the gas distribution channels 138 include second gas distribution channels 138b extending from the second side 224 to the first side 222 of the dielectric plate 152 beneath the edge ring 185. The plurality of second gas distribution channels 138b are fluidly coupled to the interface between the dielectric plate 152 and the edge ring 185. The first gas distribution channels 138a and the second gas distribution channels 138b are configured to provide backside gas, such as nitrogen (N) or helium (He), to the top surface of the dielectric plate 152 to act as a heat transfer medium. In some embodiments, the first gas distribution channels 138a are fluidly independent from the second gas distribution channels 138b within the substrate support 124 to provide independent temperature control to the substrate 122 and the edge ring 185.

Referring back to FIG. 2, in some embodiments, the base assembly 136 includes a cooling plate 220 coupled to the second side 224 of the dielectric plate 152. The cooling plate 220 includes cooling channels 228 configured to circulate a coolant to cool the dielectric plate 152. In some embodiments, the cooling channels 228 are disposed beneath the dielectric plate 152 and the edge ring 185. In some embodiments, the cooling plate 220 is made of an electrically conductive material, for example, aluminum (Al). In some embodiments, the cooling plate 220 rests on an insulator plate 226 of the base assembly 136. In some embodiments, the insulator plate 226 is made of aluminum oxide (Al₂O₃) or a polymer, such as, polyphenylene sulfide (PPS). In some embodiments, a bonding layer 248 is disposed between the cooling plate 220 and the dielectric plate 152 and configured to enhance thermal coupling therebetween. In some embodiments, the bonding layer 248 has a thermal conductivity of about 0.2 W/mK to about 1.2 W/mk.

The cooling plate 220 may have common or separate cooling channels for an inner region corresponding with the substrate 122 and an outer region corresponding with the edge ring 185. In some embodiments, the cooling plate 220 may include a thermal break disposed between the inner region and the outer region. Separate heat exchangers may be used to allow different temperature control setpoints for the inner region and the outer region.

In some embodiments, the chamber 100 includes a power supply, for example, the bias power supply 117, configured to provide power to both the substrate 122 and the edge ring 185. In some embodiments, the bias power supply 117 is electrically coupled to the cooling plate 220 to create a similar bias voltage on the substrate 122 and the edge ring 185. In operation, the bias power supply 117 applied on the cooling plate 220 creates a sheath in between the substrate 122 and the plasma 102 and between the edge ring 185 and the plasma 102. As a result, ions from the plasma 102 are attracted to the substrate 122 that is biased, and the ions accelerate through the sheath perpendicular to equipotential lines within the sheath. The similar bias voltage on the substrate 122 and the edge ring 185 minimizes tilting of the equipotential lines of the sheath over the substrate 122 and the edge ring 185. When the edge ring 185 erodes over time due to processing causing a shape of the sheath to bend proximate an edge of the substrate 122, the edge ring 185 may be replaced. In some embodiments, the substrate 122 and edge ring 185 may have independent power supplies to provide independent control of the bias voltage.

A lower edge ring 232 may be disposed about the insulator plate 226 and be made of a material different than the insulator plate 226. The lower edge ring 232 is configured to protect an outer edge of the insulator plate 226 from an unintentional plasma discharge. In some embodiments, the lower edge ring 232 is made of a ceramic material, for example, aluminum oxide (Al₂O₃). In some embodiments, the lower edge ring 232 is disposed beneath an outer peripheral portion of the dielectric plate 152. In some embodiments, the lower edge ring 232 is disposed beneath the edge ring 185.

In some embodiments, a quartz ring 230 is disposed about the dielectric plate 152 and the edge ring 185. In some embodiments, the quartz ring 230 includes a notched upper inner edge 244 configured to support an outer edge 246 of the edge ring 185. In some embodiments, an edge ring lift mechanism 250 is configured to selectively raise or lower the edge ring 185 to facilitate replacement of the edge ring 185. In some embodiments, the edge ring lift mechanism 250 is the second lift mechanism 132. In some embodiments, the edge ring lift mechanism 250 comprises one or more pins that extend through openings in the second edge ring 234 and the quartz ring 230 to directly raise the edge ring 185, for example, at the outer edge 246 of the edge ring 185. Alternatively, an edge ring lift mechanism 250′ is configured to selectively raise or lower the quartz ring 230 to raise or lower the edge ring 185 disposed thereon to facilitate replacement of the edge ring 185. In some embodiments, the edge ring lift mechanism 250′ comprises one or more pins that extend through the opening in the second edge ring 234. In some embodiments, the quartz ring 230 rests on a second edge ring 234. The second edge ring 234 may be coupled to the edge ring lift mechanism 250 to raise or lower the quartz ring 230. The second edge ring 234 is disposed about at least one of the dielectric plate 152, the cooling plate 220, the edge ring 232, and the insulator plate 226. In some embodiments, the second edge ring 234 is made of quartz.

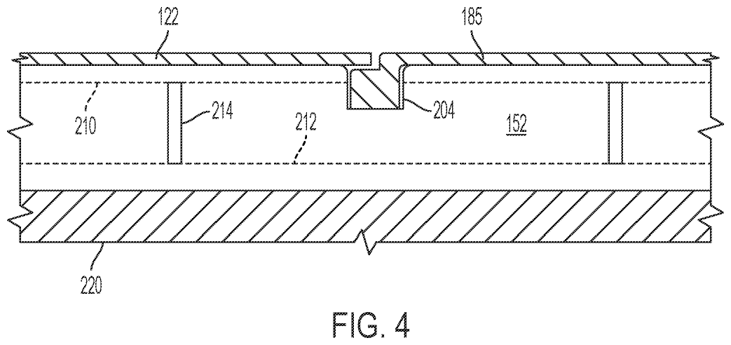

FIG. 4 depicts a cross-sectional schematic partial side view of a substrate support in accordance with at least some embodiments of the present disclosure. In some embodiments, as shown in FIG. 4, the insert ring 206 and the edge ring 185 comprise a unitary body. In such embodiments, the insert ring 206 and the edge ring 185 may be replaced together. In some embodiments, the insert ring 206 and the edge ring 185 are made of the same material.

FIG. 5 depicts a schematic side view of a portion of a process chamber (chamber 100) having a substrate support 124 in accordance with at least some embodiments of the present disclosure. In some embodiments, the pedestal 150 may be directly coupled to the chamber body 106 via the base assembly 136. The base assembly 136 may comprise a base plate 502 coupled to the chamber body 106. In some embodiments, the insulator plate 226 rests on the base plate 502. In some embodiments, the base plate 502, together with the chamber body 106, define a lower volume 506 of the chamber 100. In some embodiments, the lower volume 506 may be at atmospheric pressure during use.

One or more supplies 510 are coupled to the substrate support 124 and comprises one or more of the backside gas supply 141, the chucking power supply 140, the RF plasma power supply 170, the bias power supply 117. In some embodiments, the one or more supplies 510 are coupled to the substrate support 124 via one or more conduits that extend through the lower volume 506.

In some embodiments, the substrate support 124 includes an edge ring lift mechanism 250 comprising one or more lift pins for selectively raising or lowering the edge ring 185 onto or off of the dielectric plate 152. In some embodiments, the edge ring lift mechanism 250 extends through one or more of the base plate 502, the lower edge ring 232, the cooling plate 220, and the dielectric plate 152. In some embodiments, the substrate support 124 includes a substrate lift 520 comprising one or more lift pins for selectively raising or lowering the substrate 122 onto or off of the dielectric plate 152.

In some embodiments, the substrate support 124 may include a liner 504 disposed about the pedestal 150. In some embodiments, one or more of the liner 504 and the base plate 502 are grounded during use. In some embodiments, the liner 504 comprises an inner wall 503 and an outer wall 505 defining an annular channel 512 therebetween. In some embodiments, the inner wall 503 and the outer wall 505 are coupled to a lower plate 507 of the liner 504. In some embodiments, the lower plate 507 includes one or more openings 514 coupled to the vacuum system 114.

While the foregoing is directed to embodiments of the present disclosure, other and further embodiments of the disclosure may be devised without departing from the basic scope thereof.

1. A substrate support for use in a substrate processing chamber, comprising:
a dielectric plate having a first side configured to support a substrate having a given diameter and including an annular groove disposed in the first side, wherein the annular groove has an inner diameter that is less than the given diameter and an outer diameter that is greater than the given diameter, wherein the dielectric plate includes one or more chucking electrodes;
an insert ring disposed in the annular groove of the dielectric plate; and
an edge ring disposed on the dielectric plate, wherein the edge ring has an inner diameter that is greater than the given diameter and less than the outer diameter of the annular groove such that the edge ring is disposed over a portion of the insert ring.

2. The substrate support of claim 1, wherein at least one of:
the edge ring is made of silicon, silicon carbide, silicon dioxide, or silicon nitride; or
the insert ring is made of silicon, silicon nitride, silicon carbide, or silicon oxide.

3. The substrate support of claim 1, wherein the dielectric plate includes one or more backside gas channels fluidly coupled to an interface between the dielectric plate and the edge ring.

4. The substrate support of claim 1, wherein the insert ring and the edge ring comprise a unitary body.

5. The substrate support of claim 1, wherein at least one of:
an inner diameter of the edge ring is about 297 mm to about 302 mm; or
an outer diameter of the edge ring is about 350 mm to about 450 mm.

6. The substrate support of claim 1, further comprising a cooling plate coupled to a second side of the dielectric plate, opposite the first side, wherein the cooling plate includes cooling channels configured to circulate a coolant.

7. The substrate support of claim 1, dielectric plate further comprising a heating element disposed in the dielectric plate.

8. The substrate support of claim 1, wherein a thickness of the edge ring is about 650 micrometers to about 1300 micrometers.

9. The substrate support of claim 1, wherein a thickness of the insert ring is about 3 to about 11 millimeters.

10. The substrate support of claim 1, wherein the edge ring comprises a flat circular disk with a central opening.

11. A substrate support for use in a substrate processing chamber, comprising:
a dielectric plate having a first side configured to support a substrate having a given diameter and including an annular groove disposed in the first side and a second side opposite the first side, wherein the annular groove has an inner diameter that is less than the given diameter and an outer diameter that is greater than the given diameter, wherein the dielectric plate includes one or more chucking electrodes;
an insert ring disposed in the annular groove of the dielectric plate, wherein an upper surface of the insert ring is coplanar with an upper surface of the dielectric plate; and
an edge ring disposed on the dielectric plate, wherein the edge ring has an inner diameter that is greater than the given diameter and less than the outer diameter of the annular groove such that the edge ring is disposed over a portion of the insert ring.

12. The substrate support of claim 11, wherein the one or more chucking electrodes comprise an upper electrode, a lower electrode, and a plurality of posts coupling the upper electrode to the lower electrode.

13. The substrate support of claim 12, wherein the one or more chucking electrodes extend radially outward of the annular groove and beneath the edge ring.

14. The substrate support of claim 11, further comprising a gas distribution channel extending from the second side to the first side of the dielectric plate.

15. The substrate support of claim 11, wherein the edge ring is made of a different material than the insert ring.

16. A process chamber for processing a substrate, comprising:
a chamber body having a substrate support disposed within an inner volume of the chamber body, wherein the substrate support includes:
a cooling plate;
a dielectric plate having a first side configured to support a substrate having a given diameter and including an annular groove disposed in the first side, wherein the annular groove has an inner diameter that is less than the given diameter and an outer diameter that is greater than the given diameter, wherein the dielectric plate includes one or more chucking electrodes;
an insert ring disposed in the annular groove of the dielectric plate; and
an edge ring disposed on the dielectric plate, wherein the edge ring has an inner diameter that is greater than the given diameter and less than the outer diameter of the annular groove such that the edge ring is disposed over a portion of the insert ring, and wherein the dielectric plate includes gas distribution channels disposed below the edge ring.

17. The process chamber of claim 16, further comprising a power supply configured to provide power to both the substrate and the edge ring.

18. The process chamber of claim 16, further comprising a quartz ring disposed about the dielectric plate, wherein the quartz ring is configured to support an outer edge of the edge ring.

19. The process chamber of claim 16, further comprising an edge ring lift mechanism for selectively raising or lowering the edge ring via one or more lift pins.

20. The process chamber of claim 19, wherein the one or more lift pins are configured to extend through the dielectric plate.
